(19) United States
(12) Patent Application Publication
(10) Pub. No.: US 2012/0171377 A1
(43) Pub. Date: Jul. 5, 2012

(54) WAFER CARRIER WITH SELECTIVE CONTROL OF EMISSIVITY

(75) Inventors: Boris Volf, Hillsborough, NJ (US); Guanghua Wei, Somerset, NJ (US); Yuliy Rashkovsky, Millburn, NJ (US)

(73) Assignee: VEECO INSTRUMENTS INC., Plainview, NY (US)

(21) Appl. No.: 12/981,864

(22) Filed: Dec. 30, 2010

(51) Int. Cl. C23C 16/46; C23C 16/458

(52) U.S. Cl. 427/255.28; 118/500; 118/725

(57) ABSTRACT

A wafer carrier for use in a chemical vapor deposition apparatus includes at least one region on its outer surface having a substantially different (e.g., lower) emissivity than other regions on the outer surface. The modified emissivity region may be located on the outer edge, the top surface, and/or the bottom surface of the carrier. The region may be associated with one or more wafer pockets of the wafer carrier. The modified emissivity region may be shaped and sized so as to modify the heat transmission through the region, and thereby increase the temperature uniformity across portions of the top surface of the wafer carrier or across individual wafers. The modified emissivity region may be provided by a coating on the outer surface of the wafer carrier.

### BACKGROUND OF THE INVENTION

The present invention relates to wafer processing apparatus, to wafer carriers for use in such processing apparatus, and to methods of controlling the emissivity of such wafer carriers.

Many semiconductor devices are formed by processes performed on a substrate. The substrate typically is a slab of a crystalline material, commonly referred to as a “wafer.” One common process for forming devices on a wafer is epitaxial growth.

For example, devices formed from compound semiconductors such as III-V semiconductors typically are formed by growing successive layers of a compound semiconductor using metal organic chemical vapor deposition or “MOCVD.” In this process, the wafers are exposed to a combination of gases, typically including a metal organic compound as a source of a group III metal, and also including a source of a group V element which flow over the surface of the wafer while the wafer is maintained at an elevated temperature. Typically, the metal organic compound and group V source are combined with a carrier gas which does not participate appreciably in the reaction as, for example, nitrogen. One example of a III-V semiconductor is gallium nitride, which can be formed by reaction of an organo gallium compound and ammonia on a substrate having a suitable crystal lattice spacing, as for example, a sapphire wafer. Typically, the wafer is maintained at a temperature on the order of 500-1200° C. during deposition of gallium nitride and related compounds.

Composite devices can be fabricated by depositing numerous layers in succession on the surface of the wafer under slightly different reaction conditions, as for example, additions of other group III or group V elements to vary the crystal structure and bandgap of the semiconductor. For example, in a gallium nitride based semiconductor, indium, aluminum or both can be used in varying proportion to vary the bandgap of the semiconductor. Also, p-type or n-type dopants can be added to control the conductivity of each layer. After all of the semiconductor layers have been formed and, typically, after appropriate electric contacts have been applied, the wafer is cut into individual devices. Devices such as light-emitting diodes (“LEDs”), lasers, and other electronic and optoelectronic devices can be fabricated in this way.

In a typical chemical vapor deposition process, numerous wafers are held on a device commonly referred to as a wafer carrier so that a top surface of each wafer is exposed at the top surface of the wafer carrier. The wafer carrier is then placed into a reaction chamber and maintained at the desired temperature while the gas mixture flows over the surface of the wafer carrier. It is important to maintain uniform conditions at all points on the top surfaces of the various wafers on the carrier during the process. Minor variations in composition of the reactive gases and in the temperature of the wafer surfaces cause undesired variations in the properties of the resulting semiconductor devices.

For example, if a gallium and indium nitride layer is deposited, variations in wafer surface temperature or concentrations of reactive gases will cause variations in the composition and bandgap of the deposited layer. Because indium has a relatively high vapor pressure, the deposited layer will have a lower proportion of indium and a greater bandgap in those regions of the wafer where the surface temperature is higher. If the deposited layer is an active, light-emitting layer of an LED structure, the emission wavelength of the LEDs formed from the wafer will also vary. Thus, considerable effort has been devoted in the art heretofore towards maintaining uniform conditions.

One type of CVD apparatus which has been widely accepted in the industry uses a wafer carrier in the form of a large disc with numerous wafer-holding regions, each adapted to hold one wafer. The wafer carrier is supported on a spindle within the reaction chamber so that the top surface of the wafer carrier having the exposed surfaces of the wafers faces upwardly toward a gas distribution element. While the spindle is rotated, the gas is directed downwardly onto the top surface of the wafer carrier and flows across the top surface toward the periphery of the wafer carrier. The used gas is evacuated from the reaction chamber through ports disposed below the wafer carrier.

The wafer carrier is maintained at the desired elevated temperature by heating elements, typically electrical resistive heating elements disposed below the bottom surface of the wafer carrier. One example of such radiant heating elements is disclosed in U.S. Pat. No. 5,759,281, the disclosure of which is hereby incorporated by reference herein. Typical heating elements are maintained at a temperature above the desired temperature of the wafer surfaces, and heat is transferred from the heating elements to the bottom surface of the wafer carrier and flows upwardly through the wafer carrier to the individual wafers. The gas distribution element and the walls of the reaction chamber typically are maintained at temperatures substantially below the desired temperature of the wafer surfaces, and therefore heat is continually transferred from the wafer carrier and wafers to the walls and gas distribution element. Thus, heat must be continually transferred from the heating element to the wafer carrier and wafers.

Although considerable effort has been devoted in the art heretofore to optimization of such systems, still further improvement would be desirable. In particular, it would be desirable to provide better uniformity of temperature across the surface of each wafer, and better temperature uniformity across the entire wafer carrier.

### BRIEF SUMMARY OF THE INVENTION

One aspect of the present invention provides a wafer carrier. A wafer carrier according to this aspect of the invention desirably includes a body having an outer surface. Preferably, the outer surface of the body includes oppositely-facing top and bottom surfaces and an edge surface extending between the top and bottom surfaces. The top surface preferably defines a plurality of pockets adapted to receive wafers. Desirably, the outer surface of the body includes a first region having a substantially different emissivity than other regions of the outer surface. According to this aspect of the invention, the emissivity of the first region may be substantially lower than the other regions of the outer surface.

According to one aspect of the invention, the first region may be disposed on the edge surface of the wafer carrier body. The outer surface of the body may include additional regions having a substantially different emissivity than other regions of the outer surface. The additional regions may be disposed on the bottom surface or the top surface of the wafer carrier body. The body of the wafer carrier may be in the form of a circular disc having a central axis, and the additional regions may each have the shape of a ring centered on the central axis.

According to another aspect of the invention, the first region may be associated with at least one of the plurality of pockets. The first region may be disposed on the top surface of the wafer carrier adjacent to the at least one pocket. The first region may be disposed in one of the pockets.

According to any of the aspects of the invention, the first region of the outer surface of the wafer carrier body may include a coating having an emissivity substantially lower than the other regions of the outer surface. The first region may define an emissivity gradient across at least a portion of the first region.

A further aspect of the invention provides a chemical vapor deposition apparatus incorporating a wafer carrier as discussed above.

Another aspect of the invention provides a method of processing wafers disposed in the pockets of a wafer carrier as discussed above.

### BRIEF DESCRIPTION OF THE DRAWINGS

FIG. 1 is a simplified, schematic sectional view depicting chemical vapor deposition apparatus in accordance with one embodiment of the invention.

FIGS. 2A and 2B are fragmentary, diagrammatic sectional views of portions of wafer carriers usable in the apparatus of FIG. 1.

FIGS. 3A and 3B are graphs illustrating exemplary operating temperature profiles along portions of the wafer carriers of FIGS. 2A and 2B.

FIG. 4 is a partial sectional view depicting chemical vapor deposition apparatus in accordance with an embodiment of the invention.

FIG. 5 is a graph illustrating exemplary operating temperature profiles along portions of the wafer carriers of FIGS. 2A and 4.

FIG. 6 is a diagrammatic plan view illustrating aspects of a wafer carrier in accordance with one embodiment of the invention.

FIG. 7 is a fragmentary, diagrammatic sectional view of a portion of a wafer carrier in accordance with an embodiment of the invention.

FIG. 8 is a fragmentary, diagrammatic plan view of a portion of a wafer carrier in accordance with an embodiment of the invention.

### DETAILED DESCRIPTION

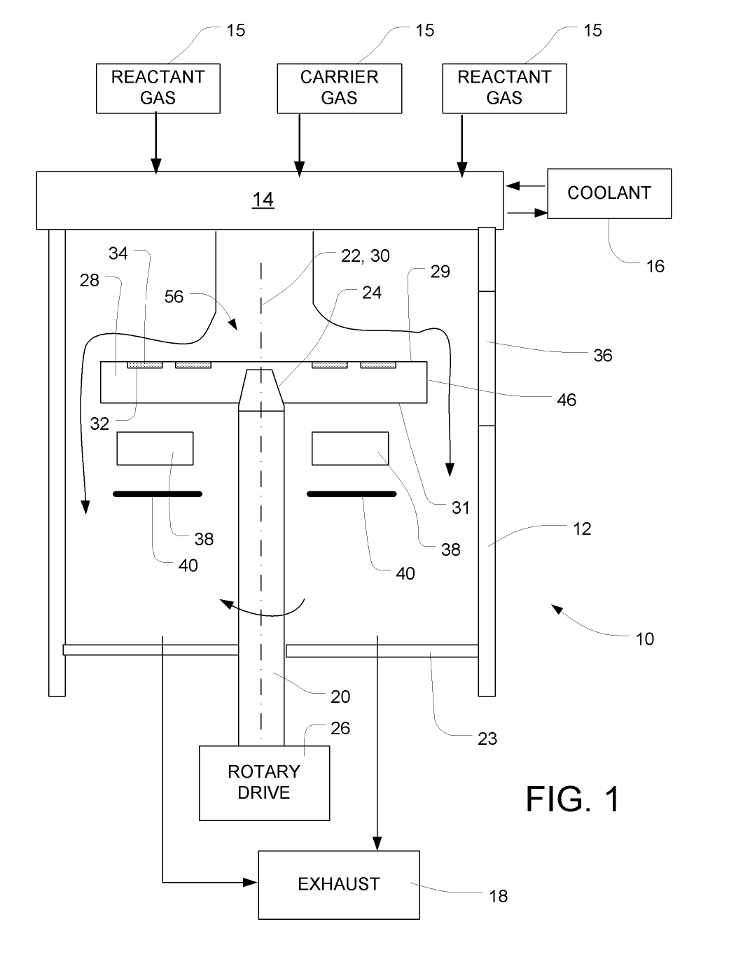

Referring to FIG. 1, a chemical vapor deposition apparatus 10 in accordance with one embodiment of the invention includes a reaction chamber 12 having a gas distribution element 14 arranged at one end of the chamber 12. The end of the chamber 12 having the gas distribution element 14 is referred to herein as the “top” end of the chamber 12. This end of the chamber typically, but not necessarily, is disposed at the top of the chamber in the normal gravitational frame of reference. Thus, the downward direction as used herein refers to the direction away from the gas distribution element 14; whereas the upward direction refers to the direction within the chamber, toward the gas distribution element 14, regardless of whether these directions are aligned with the gravitational upward and downward directions. Similarly, the “top” and “bottom” surfaces of elements are described herein with reference to the frame of reference of chamber 12 and element 14.

The gas distribution element 14 is connected to sources 15 of gases to be used in the wafer treatment process, such as a carrier gas and reactant gases (e.g., a group III metal, typically a metalorganic compound, and a group V element as, for example, ammonia or other group V hydride). In a typical chemical vapor deposition process, the carrier gas can be nitrogen, and hence the process gas at the top surface of a wafer carrier can be predominantly composed of nitrogen with some amount of the reactive gas components. The gas distribution element 14 is arranged to receive the various gases and direct a flow of process gases generally in the downward direction. The gas distribution element 14 desirably is also connected to a coolant system 16 arranged to circulate a liquid through the gas distribution element 14 so as to maintain the temperature of the element at a desired temperature during operation. A similar coolant arrangement (not shown) can be provided for cooling the walls of chamber 12. Chamber 12 is also equipped with an exhaust system 18 arranged to remove spent gases from the interior of the chamber through ports (not shown) at or near the bottom of the chamber so as to permit continuous flow of gas in the downward direction from the gas distribution element.

A spindle 20 is arranged within the chamber so that the central axis 22 of the spindle 20 extends in the upward and downward directions. The spindle 20 is mounted to the chamber by a conventional rotary pass-through device (not shown) incorporating bearings and seals, so that the spindle can rotate about the central axis 22 while maintaining a seal between the spindle 20 and the bottom 23 of the chamber 12. The spindle 20 has a fitting 24 at its top end, i.e., at the end of the spindle closest to the gas distribution element 14. In the particular embodiment depicted, the fitting 24 is a generally frustoconical element tapering toward the top end of the spindle 20 and terminating at a flat top surface. A frustoconical element is an element having the shape of a frustum of a cone. The spindle 20 is connected to a rotary drive mechanism 26 such as an electric motor drive, which is arranged to rotate the spindle about the central axis 22. The spindle 20 can also be provided with internal coolant passages extending generally in the axial directions of the spindle within the gas passageway. The internal coolant passages can be connected to a coolant source, so that a fluid coolant can be circulated by the source through the coolant passages and back to the coolant source.

In the operative condition depicted in FIG. 1, a wafer carrier 28 is mounted on the fitting 24 of the spindle 20. The wafer carrier 28 is desirably detachably mounted on the fitting 24. The wafer carrier 28 includes a body generally in the form of a circular disc having a central axis 30 coincident with the axis 22 of the spindle 20. The carrier 28 has generally planar top 29 and bottom 31 surfaces extending generally parallel to one another and generally perpendicular to the central axis 30 of the disc. The carrier 28 also has a plurality of generally circular wafer-holding pockets 32 extending downwardly into the carrier 28 from the top surface 29 thereof, each pocket adapted to hold a wafer 34.

Merely by way of example, the wafer carrier 28 may be about 465 mm in diameter, and the thickness of the carrier between top surface 29 and bottom surface 31 may be on the order of 15.9 mm. The wafer carrier 28 is preferably formed from materials which do not contaminate the CVD process and which can withstand the temperatures and chemistries encountered in the process. For example, the wafer carrier 28 desirably is formed as a monolithic slab of a non-metallic refractory material as, for example, a material selected from the group consisting of silicon carbide, boron nitride, boron carbide, aluminum nitride, alumina, sapphire, quartz, graphite, and combinations thereof, with or without a refractory coating as, for example, a carbide, nitride or oxide. The wafer carrier 28 can be formed as a single piece or as a composite of plural pieces. For example, as disclosed in U.S. Pulished Patent Application No. 2009/0155028, the disclosure of which is hereby incorporated by reference herein, the wafer carrier body may include a hub defining a small region of the body surrounding the central axis 30 and a larger portion defining the remainder of the disc-like body.

A wafer 34, such as a disc-like wafer formed from sapphire, silicon carbide, silicon, or other crystalline substrate, may be disposed within each pocket 32 of the wafer carrier 28. Typically, each wafer 34 has a thickness which is small in comparison to the dimensions of its major surfaces. For example, a circular wafer 34 about 2 inches (50 mm) in diameter may be about 430 μm thick or less. Each wafer 34 is disposed with a top surface thereof facing upwardly, so that the top surface is exposed at the top of the wafer carrier 28.

The chamber 12 is provided with a port 36 leading to an antechamber (not shown), so that the wafer carrier 28 may be moved into and out of the chamber 12. A shutter (not shown) may also be provided for closing and opening the port 36. The apparatus 10 can further include a loading mechanism (not shown) capable of moving the wafer carrier 28 from the antechamber into the chamber 12 and engaging the wafer carrier 28 with the spindle 20 in the operative condition, and also capable of moving the wafer carrier 28 off of the spindle 20 and into the antechamber.

A heater 38 is mounted within the chamber 12 and surrounds the spindle 20 below the fitting 24. The heater 38 is arranged to transfer heat towards the bottom surface 31 of the wafer carrier 28, principally by radiant heat transfer. Heat applied to the bottom surface 31 of the wafer carrier 28 preferably flows upwardly through the wafer carrier 28 towards the top surface 29 thereof, where it heats the wafers 34 and the process gases passing over the top surface 29 of the wafer carrier 28. One or more heat shields 40 may also be mounted below the heater 38.

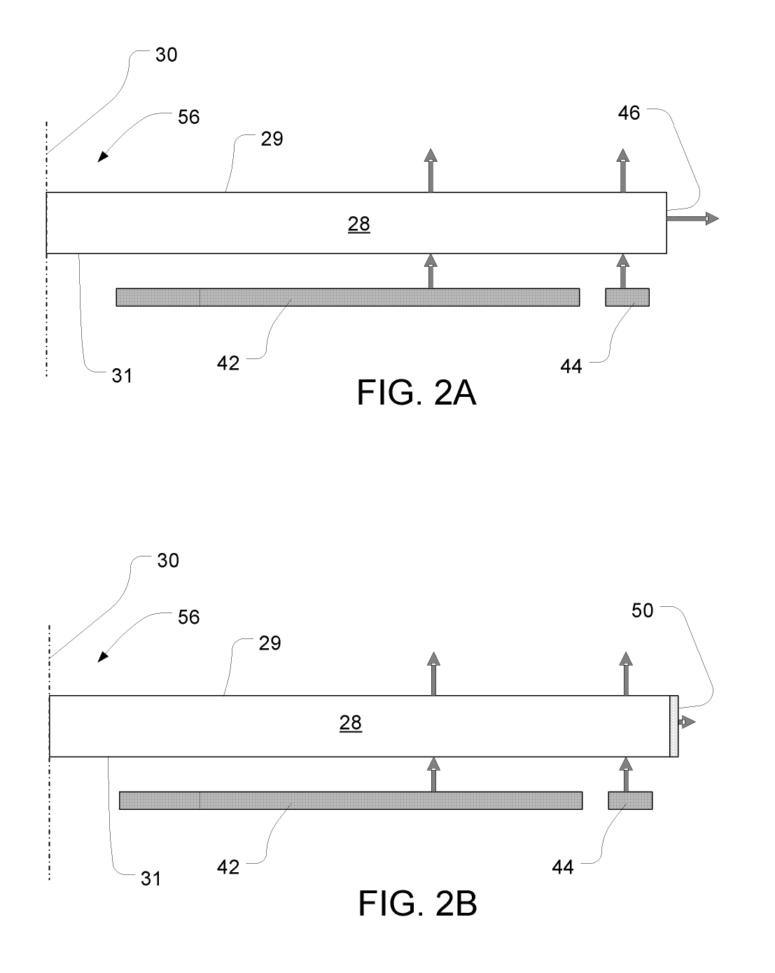

The heater 38 may include a plurality of individually adjustable radial zones, in order to better control temperature uniformity across the wafer carrier 28. For example, each zone of the heater 38 may include a separate heating element, where the power supplied to each heating element can be individually controlled. One example of a deposition reactor having heating elements arranged in multiple zones is disclosed in U.S. Pat. No. 6,492,625, the disclosure of which is hereby incorporated by reference herein. As shown in FIG. 2A, the heater 38 may have two zones, comprising independent inner heating element 42 and outer heating element 44. During steady-state operation of the apparatus 10, the inner heating element 42 is desirably adjusted so that heat transfer from the inner heating element 42 to the wafer carrier 28 balances the heat loss from the top surface 29 of the wafer carrier 28 in the region of the wafer carrier generally heated by the inner heating element 42. Similarly, the outer heating element 44 is desirably adjusted so that heat transfer from the outer heating element 44 to the wafer carrier 28 balances both the heat loss from the top surface 29 of the wafer carrier 28 in the region of the wafer carrier generally heated by the outer heating element 44 and also the heat loss from the outer edge 46 of the wafer carrier 28. As shown in FIG. 2A, the inner heating element 42 preferably covers a substantially larger area of the wafer carrier 28 than the outer heating element 44.

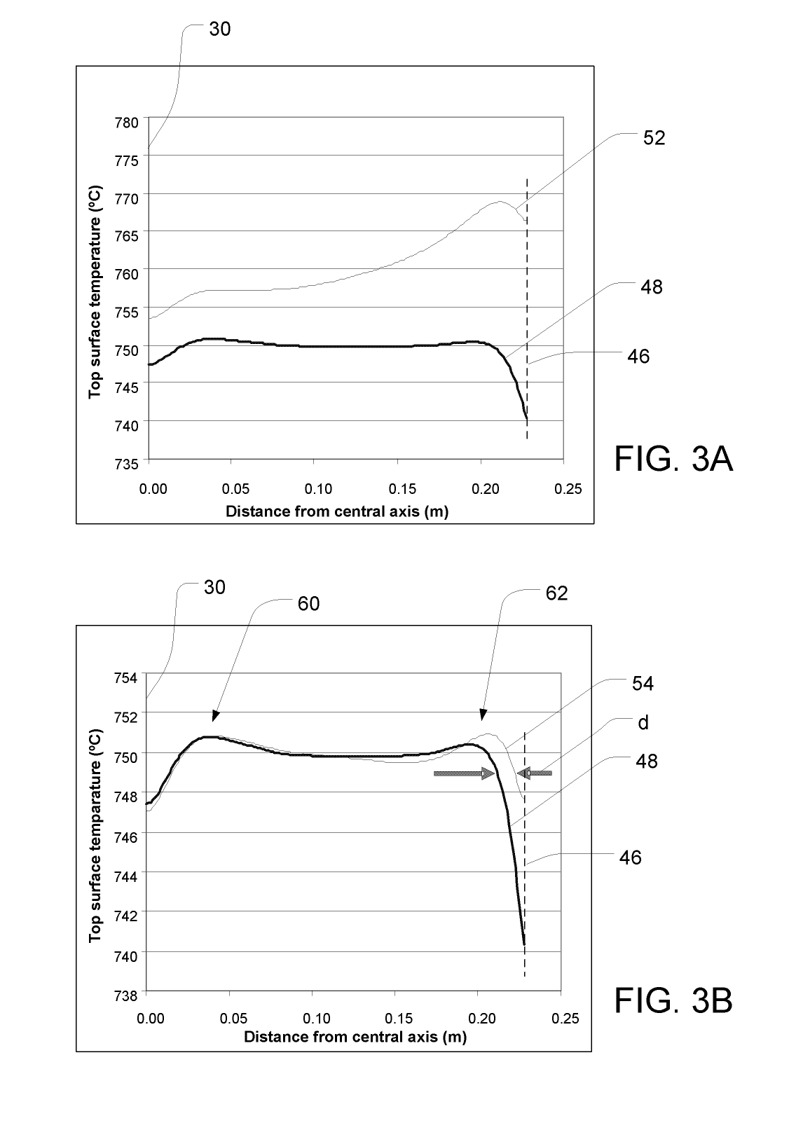

To compensate for the heat loss from the additional surface area of the outer edge 46 of the wafer carrier 28, the outer heating element 44 may need to apply more power per unit area of the bottom surface than the inner heating element 42, in order to keep the temperature across the top surface 29 as uniform as possible. Curve 48 in the graph of FIG. 3A illustrates an exemplary radial temperature profile along the top surface 29 of the wafer carrier 28 from the central axis 30 to the outer edge 46. In FIG. 3A, the outer heating element 44 has been adjusted so as to keep the curve 48 as flat (i.e., uniform temperature) as possible. However, as curve 48 illustrates, even with the outer heating element 44 adjusted, the temperature may still drop off significantly near the outer edge 46 of the wafer carrier 28. This can cause non-uniform temperature across any wafers 34 near the outer edge 46. To maintain temperature uniformity within design limits, the outermost wafer can be positioned remote from outer edge 46. However, results in a reduction of the amount of the top surface 29 that can be used to hold wafers 34.

In accordance with one embodiment of the invention, the outer edge 46 of the wafer carrier 28 is provided with a lower emissivity than the other surfaces of the carrier 28, in order to reduce heat transmission through the outer edge 46. Emissivity is a dimensionless quantity representing the ratio of energy radiated by a unit area of the material to the energy radiated by a unit area of a theoretical “black body” at the same temperature. The value of emissivity for a particular material is dependent on the wavelength of the energy. However, the emissivity of a material can be assumed to have a particular, constant value with respect to a relatively narrow range of relevant wavelengths (e.g., the dominant frequencies emitted by the heater 38).

As shown in FIG. 2B, the emissivity of the outer edge 46 may be lowered by including a coating 50 having a lower emissivity than the material of the wafer carrier 28. Although the coating 50 is shown as covering the entire outer edge 46, that is not required. Any difference between the emissivity of the coating 50 and the wafer carrier 28 may be used, and the difference is desirably as high as possible. A preferred coating 50 may have an emissivity between about 0.4 and 0.8 lower than the emissivity of the wafer carrier 28, with one preferred emissivity difference being about 0.6. For example, a wafer carrier 28 constructed from the materials discussed above may have an emissivity of about 0.85, while a desirable coating 50 may have an emissivity of about 0.25. Reducing the emissivity of the outer edge 46 reduces radiation from the outer edge 46 of the wafer carrier 28. This is illustrated by curve 52 in FIG. 3B, in which the heaters 42 and 44 are operating at the same power level as was used in creating curve 48, and, as a result, the temperature near the outer edge 46 is higher in curve 52 than in curve 48.

Curve 54 in FIG. 3B illustrates the radial temperature profile along the top surface 29 of the wafer carrier 28 of FIG. 2B (which has the coating 50 located on its outer edge 46), where the outer heating element 44 has been adjusted to keep the curve 54 as flat as possible. Curve 48 is overlayed for comparison. As illustrated by distance d in FIG. 3B, within a particular temperature deviation (e.g., 1° C.) from the desired temperature (e.g., 750° C.), curve 54 extends closer to the outer edge 46 of the carrier 28 than curve 48. This desirably leads to better temperature uniformity across the wafers 34 near the outer edge 46, and it desirably creates additional space on the top surface 29 that can be used to hold wafers 34.

The above technique of selectively modifying the emissivity of the wafer carrier 28 can also be used to increase temperature uniformity in other portions of the wafer carrier. For example, as shown in FIGS. 3A-B, the top surface temperature also drops in a central region 56 near the central axis 30 of the wafer carrier 28. This may be due to various factors. For example, because the spindle 20 is supporting the wafer carrier 28 along the central axis 30, there may not be any portion of the heater 38 below the central region of the carrier 28. Additionally, the spindle 20 may act as a heat sink, particularly if the spindle 20 is provided with internal coolant passages, as discussed above.

In accordance with an embodiment of the invention, a portion of the top surface 29 of the wafer carrier 28 in the central region 56 may be provided with a lower emissivity than other surfaces of the carrier 28. In this manner, the top surface 29 of the wafer carrier 29 may lose less heat than the other surfaces of the carrier 28, thus increasing the temperature in the central region 56.

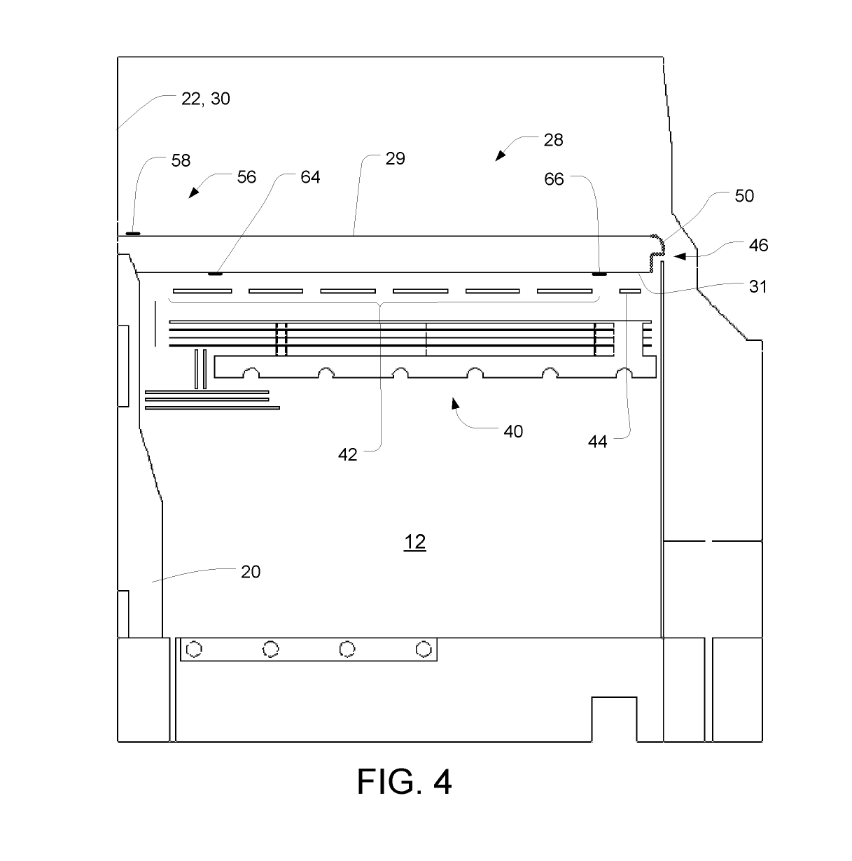

In one example, as illustrated in FIG. 4, a low-emissivity coating in the shape of a ring 58 centered on the central axis 30 may be provided on the top surface 29 of the wafer carrier 28. A ring shape may be desirable, for example, where a pyrometer is used to measure the temperature of the top surface 29 at the center of the carrier 28. However, the coating could also be in the shape of a circle, filling all or a portion of the central region 56. The ring 28 is preferably dimensioned such that, in combination with adjustments to the power supplied to the heating elements, a desired temperature profile across the top surface 29 of the wafer carrier 28 is obtained. The specific dimensions and emissivity properties of the ring 28 will, of course, be influenced by various factors specific to the particular apparatus 10, including the emissivity properties and dimensions of the wafer carrier 28 and the particular temperature profiles to be modified. The particular dimensions for the ring 28 may thus be determined through computer modeling or physical testing.

Other low-emissivity rings may similarly be used to even out undesirable temperature fluctuations across the top surface 29 of the wafer carrier 28. For example, as shown in FIG. 3B, both temperature curves 48 and 54 increase and form slight peak regions 60, 62 before dropping off near both the central axis 30 and the outer edge 46. Accordingly, FIG. 4 illustrates low-emissivity coated inner 64 and outer 66 rings on the bottom surface 31 of the wafer carrier 28 and centered on the central axis 30. By providing such low-emissivity rings 64, 66 on the bottom surface, the amount of heat absorbed by the wafer carrier 28 at those locations will desirably be reduced. According to Kirchhoff's law, at thermal equilibrium, the emissivity of a body equals its absorptivity. Thus, the low-emissivity rings will have lower absorptivity. Absorptivity is a dimensionless quantity representing the ratio of energy absorbed by a unit area of a material to the energy absorbed by a unit area of a theoretical “black body” at the same temperature. As a result, if less heat is absorbed by the wafer carrier 28 at the locations of the rings 64, 66, the temperature of the top surface 29 of the carrier 28 near those locations should be reduced. Thus, the rings 64, 66 should be dimensioned and located so as to reduce the temperature of the peak regions 60, 62, or to produce any other desired change to the temperature profile of the top surface 29.

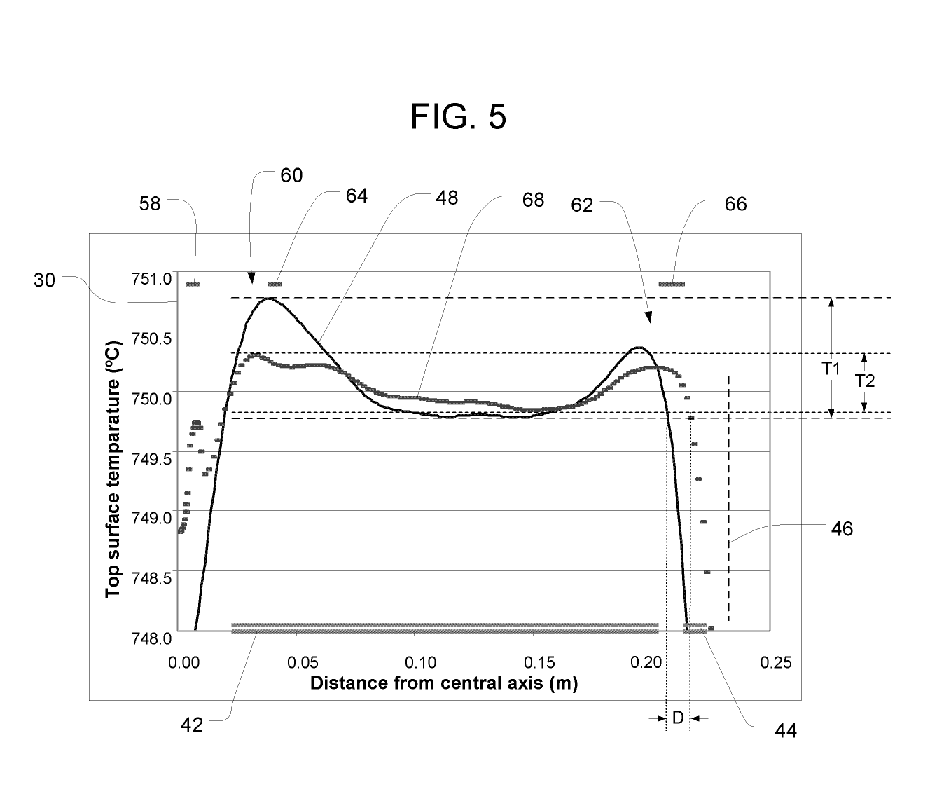

Curve 68 in FIG. 5 illustrates the radial temperature profile along the top surface 29 of a wafer carrier 28 that has been modified as discussed above, and after the heating elements 42, 44 have been adjusted to make the curve 68 as flat as possible. In particular, the wafer carrier 28 includes the coating 50 on its outer edge 46, the ring 58 on its top surface 29, and the rings 64 and 66 on its bottom surface 31. Curve 48, which illustrates the temperature profile without the emissivity modifications, is overlayed for comparison. FIG. 5 also illustrates the radial positions of the rings 58, 64, 66 and heating elements 42, 44.

As FIG. 5 shows, the temperature variation T2 between the peak regions 60, 62 of curve 68 is significantly less than the temperature variation T1 of curve 48 between the peak regions 60, 62. In the particular example illustrated, T2 is approximately 0.5° C., compared with approximately 1° C. for T1. Additionally, curve 68 remains within that 0.5° C. temperature zone approximately 10 mm closer to the outer edge 46 than curve 48. Thus, by adjusting the locations and sizes of various low-emissivity regions on the outer surface of the wafer carrier 28, the radial temperature profile across the top surface 29 can desirably be made more uniform and additional area for holding wafers 34 may be created on the top surface 29.

The above technique of modifying the emissivity of portions of the wafer carrier 28 need not be used only for radial temperature non-uniformities. The technique may also be used to counteract other non-uniformities, such as those caused by the layout of the wafers 34 on the carrier 28. For example, the arrangement of wafers 34 along the top surface 29 of the wafer carrier 28 may resemble concentric rings centered on the central axis 30 of the carrier 28. Another arrangement could be a close-packed (e.g., hexagonal close-packed) layout. In any case, the top surfaces of the wafers 34 are typically colder than the top surface 29 of the wafer carrier 28. Thus, the non-uniform temperature across the composite surface comprising the wafers 34 and the wafer carrier 28 can introduce non-uniformity across the top surfaces of individual wafers 34, since the temperature of each wafer 34 will be affected by its neighboring wafers. For example, during operation, when the wafer carrier 28 is rotating about its central axis 30, the downwardly directed process gases encounter the rotating wafer carrier 28 and spiral outwards. The gases are heated by contact with (i.e., conduction) and radiation from the wafer carrier 28 and the wafers 34, and thus a local temperature of any gas stream will be affected by which surfaces it has passed over. For example, a gas stream passing over a particular wafer 34 may be hotter if it has recently passed over the top surface 29 of the wafer carrier 28 instead of recently passing over the relatively colder top surface of another wafer. Therefore, the technique of modifying the emissivity of portions of the wafer carrier 28 may also be used to help counteract some of the above types of temperature non-uniformities.

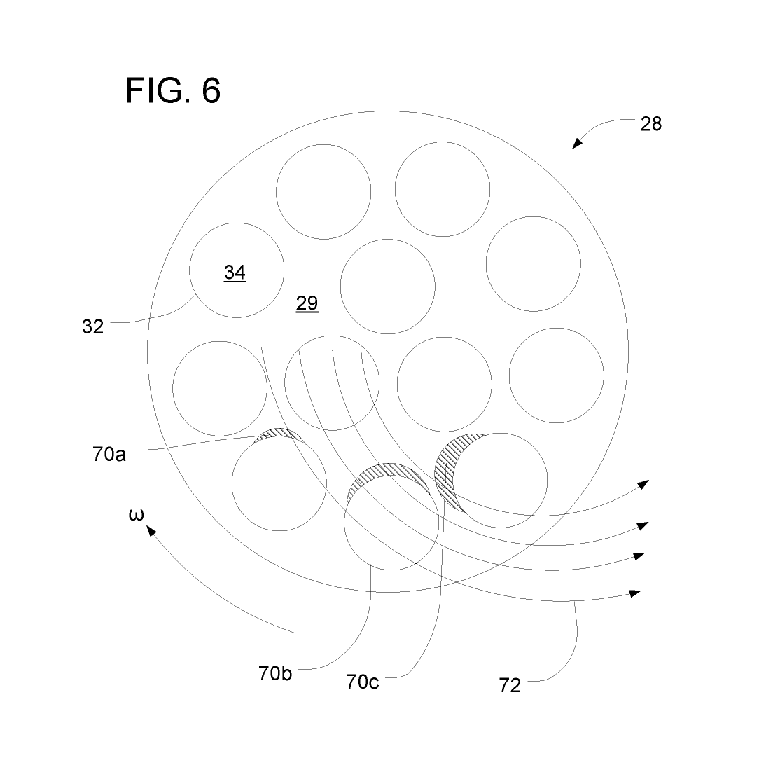

In one example, regions having a lower emissivity than the remainder of the wafer carrier 28 may be associated with individual wafer pockets 32. For example, as shown in FIG. 6, such regions 70a-c may be located on the top surface 29 of the wafer carrier 28 adjacent to the individual pockets 32. In the embodiment illustrated in FIG. 6, such lower emissivity regions 70a-c have a crescent shape. Although only three such regions 70a-c are illustrated in FIG. 6, such lower emissivity regions are also desirably provided for the other pockets 32 of the wafer carrier 28. Each crescent shaped region 70a-c is desirably arranged adjacent to a particular pocket 32 to be modified such that the widest portion of the crescent is aligned with an upstream gap between pockets 32. In that way, the hotter gases passing over the gap will pass over a lower emissivity region 70a-c before contacting the wafer 34 in the pocket 32. Since the top surface 29 in the lower emissivity region 70a-c will radiate less thermal energy than the top surface 29 in the gap, the gas passing over the region 70a-c will desirably absorb comparatively less thermal energy from the region 70a-c, which will preferably counterbalance the increased energy absorbed from the higher emissivity region of the gap.

It is noted that the temperature of the top surface 29 in the region 70a-c may be higher than the other regions of the wafer carrier 28, due to the decreased emissivity of that region (as discussed above). Therefore, the amount of thermal energy transferred to the gas by conduction may be higher from region 70a-c than from the other regions, even though the energy transfer by radiation will be lower. Typically the decrease in the heat transfer by radiation will be greater than the increase in heat transfer by conduction, so that the net heat transfer to the gas from region 70a-c is lower than from the gap on the top surface 29 of the wafer carrier 28. The amount of radiative heat transfer from region 70a-c to the gas may be based on various factors, including: the emissivity, size, and geometry of the region 70a-c; the absorbtivity of the gas; the temperature of the wafer carrier; the temperature of the surrounding environment. Computer modeling can be used to help determine whether, in a particular case, the change in radiation or the change in conduction will dominate, and to help determine how best to provide a desired increase or decrease in the temperature of the gas over a particular region. Depending on the balance of the factors discussed above, a lower emissivity in regions 70a-c may increase or decrease the gas temperature. In the event that it results in an increase in the gas temperatures, then the regions 70a-c may be designed accordingly. For example, the regions 70a-c may be provided with an emissivity higher than the remainder of the wafer carrier 28. In another example, the lower emissivity regions 70a-c may be arranged so as to increase the temperature of the cooler gases that have passed over upstream wafers (rather than reducing the temperature of the gases that have passed over the upstream gaps). With an appropriate design of the modified emissivity regions, the temperature of the gases flowing over the wafers may desirably be made more uniform.

The specific design of each of the regions 70a-c will depend on various factors, including the geometry of the wafer carrier 28 and the gas flow conditions over the top surface 29 of the carrier. Computer flow modeling can be used to determine the appropriate configuration for each region 70a-c. As illustrated in FIG. 6, with a clockwise wafer carrier rotation ω, the representative gas streams 72 may spiral outward over the top surface 29 of the wafer carrier 28. Due to the different upstream conditions for each of the wafers 34, the shape and orientation of each of the regions 70a-c will likely be different.

In another example of an emissivity modification technique, portions of the pockets 32 themselves may be provided with modified surface emissivities. This may be useful, for example, for counteracting the bowing of the wafers 34 during processing, as discussed below.

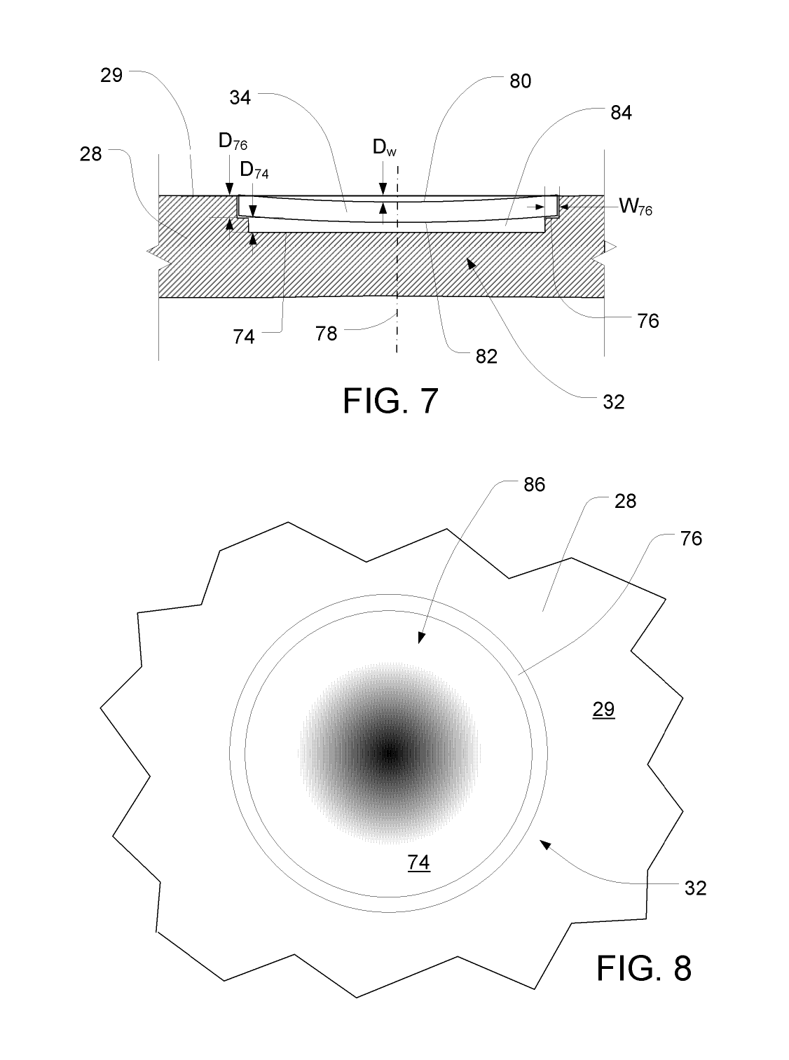

During the deposition process, wafers 34 tend to bow in a relatively predictable manner. The bowing typically arises from the difference in lattice constants between the deposited semiconductor material and the wafer, and from the thermal gradient imposed across the wafer. In the example shown in FIG. 7, the bowing makes the wafer concave in the upward direction (although wafers may also commonly bow such that they are convex in the upward direction). The degree of bowing is greatly exaggerated in FIG. 7 for clarity of illustration.

Typically, for wafers of about 50 mm diameter, such bowing D_{W} typically is on the order of about 5 μm, although greater bowing, on the order of a few tens of μm may occur in some processes with wafers of this diameter. For a given process, the bowing D_{W} tends to vary with the square of the wafer diameter. Thus, if all other factors are equal, a wafer of 6 inch nominal diameter will exhibit 9 times as much bowing as a wafer of 2-inch nominal diameter.

In the particular embodiment of a wafer carrier 28 depicted in FIG. 7, the pockets 32 have a floor surface 74 recessed below the general level of the top surface 29 of the wafer carrier. In this embodiment, floor surface 74 is nominally a flat surface, and ideally would be exactly flat. However, practical manufacturing tolerances typically limit its flatness to about 0.0005 inches (13 μm) maximum deviation from a perfectly flat plane, with any such deviation being such as to make the floor surface concave. As used in this disclosure, the term “substantially flat” should be understood as referring to a surface which is flat to within about 30 μm or less. Floor surface 74 is in the form of a circle having a central axis 78 substantially perpendicular to the general plane of the top surface 29. A support ledge 76 surrounds floor surface 74, the support ledge 76 having an upwardly facing surface which is elevated slightly above floor surface 74. The support ledge 76 is in the form of a loop encircling the floor surface 74 and concentric with the central axis 78 of the pocket 32. In an alternative, the support ledge 76 may be provided as individual pieces (e.g., tabs) disposed around the periphery of the pocket 32. In the embodiment shown, each pocket 32 is arranged to receive a wafer about 2 inches (50.8 mm) in diameter. For a nominal 2-inch (5 cm) wafer diameter, the upwardly facing surface of the support ledge 76 is at a distance on the order of about 20 μm to about 100 μm, and desirably about 20-50 μm, above floor surface 74, and the width W₇₆ of the ledge may be about 0.5-0.7 mm. For larger pockets intended to hold larger wafers, these dimensions typically would be greater. The surface of the support ledge 76 desirably is disposed in a plane parallel to the plane of floor surface 74. Support ledge 76 is also recessed below the wafer carrier top surface 29. Desirably, the distance D₇₆ from the top surface 29 to the upwardly facing surface of the support ledge 76 is about 75-175 μm more than the thickness of a wafer to be processed. For example, in a wafer carrier arranged to process sapphire wafers of 2-inch nominal diameter and 430 μm nominal thickness, D₇₆ may be about 500-600 μm.

In operation, the wafer carrier 28 is loaded with wafers 34 such that the periphery of each wafer 34 rests on the support ledge 76. Preferably, the overlap between the wafer and the support ledge is at a minimum. The top surface 80 of each wafer is nearly coplanar with the top surface 29 of the wafer carrier 28 surrounding each pocket 32. The bottom surface 82 of each wafer faces downwardly toward the floor surface 74, but is spaced above the floor surface.

During the deposition process, the temperature prevailing at the top surface 80 of each wafer 34 depends on the total thermal resistance between the heater 38 (FIG. 1) and the top surface 80 of the wafer. At any point on the top surface 80 of the wafer, the total thermal resistance is the sum of the resistance to radiant heat transfer between the heater 38 and the bottom surface 31 of the wafer carrier 28; the thermal resistance associated with conduction between the bottom surface 31 and the floor surface 74; the resistance to heat conduction and radiation across the gap 84 between the bottom surface 82 of the wafer and the floor surface 74; and the resistance to conduction through the wafer 34 itself. In practice, the resistance to radiant heat transfer between the heater 38 and the bottom surface 31 is substantially uniform across the entire wafer carrier 28. The resistance to conduction through the wafer 34 is also substantially uniform across the entire wafer 34. The heat transfer from the floor surface 74 to the bottom surface 82 of the wafer, across the gap 84, includes conduction and radiation components. The resistance to heat transfer across the gap 84 varies because of the bowing in the wafer 34. Gap 84 typically is filled with a stagnant layer of process gas. This gas has relatively low thermal conductivity, and hence, the resistance to conduction across the gap 84 provides an appreciable portion of the total resistance to heat transfer between the heater 38 and the wafer top surface 80. The thermal resistance of the gap 84 is directly related to the height of the gap 84. For those portions of the wafer 34 close to the periphery of the wafer, the height of the gap 84 is simply the height of the support ledge 76 about the floor surface 74 (i.e., D₇₄). However, adjacent the central axis 78, the height of the gap 84 is decreased by the bowing distance D_{W} of the wafer 34. Thus, the thermal resistance of the gap 84 is at a minimum near the central axis 78. As a result, the temperature of the top surface 80 of the wafer 34 will be higher near the central axis 78 than near the periphery of the wafer.

Varying the emissivity of the floor 74 of the pocket 32 may desirably counteract the effect of the varying thermal resistance of gap 84, by varying the amount of heat transfer from the floor 74 to the bottom surface 82 of the wafer 34 by radiation. For example, as shown in FIG. 8, the floor 74 of the pocket 32 may be provided with a lower emissivity region 86 centered on the central axis 78. This preferably decreases radiant heat transfer near axis 78, which desirably counteracts the higher conduction near axis 78. In an alternative example, a higher emissivity region may be provided around the periphery of the floor 74 of the pocket 32. The region 86 may desirably have a gradient, such that the emissivity decreases approaching the central axis 78. This may be achieved, for example in an embodiment in which a low emissivity coating is used to create the low emissivity region, by applying the coating in small dots, with the density of dots per unit area gradually decreasing at increasing distances away from the central axis 78.

In a case where the wafers bow such that they are convex in the upward direction, an opposite technique may be used. That is, a lower emissivity region may be provided around the periphery of the floor of the pocket, or a higher emissivity region may be provided at the center of the pocket. A gradient may also be used, such that the emissivity increases approaching the central axis of the pocket.

The emissivity of the floor 74 of each pocket 32 is desirably selected to optimize its counter-balancing effect at that stage of the process where the most critical layers of the device are formed. Thus, the bowing distance D_{W} progressively increases during deposition of the first layers, such as buffer layers, on the wafer top surface. The predicted bowing D_{W} used to select the characteristics of the low emissivity region 86 should be selected to correspond to the value of D_{W} prevailing after deposition of the buffer layers, and during deposition of the most critical layers in the device to be fabricated.

In accordance with one embodiment of the invention, a method of providing increased temperature uniformity across portions of a wafer carrier 28 or across individual wafers 34 comprises locating one or more regions on the outer surface of the wafer carrier 28 (or wafers 34) where the operating temperature deviates from a desired amount, and then modifying the wafer carrier 28 as discussed above. The particular regions on the wafer carrier may be identified, for example, by performing computer modeling or by conducting physical tests with pyrometers measuring local temperatures in different locations on the carrier. In one example, in order to improve the temperature uniformity near the outer edge 46 of the wafer carrier 28, a low-emissivity coating 50 may be provided on the outer edge 46. In another example, where the operating temperature at a particular location along the top surface 29 of the wafer carrier 28 is lower than a desired amount, a corresponding region on the top surface 29 can be provided with a lower emissivity (e.g., with ring 58) to decrease the heat loss from that region. If, on the other hand, the operating temperature at a particular location along the top surface 29 is higher than a desired amount, a corresponding region on the bottom surface 31 can be provided with a lower emissivity (e.g., with ring 64 or 66) to decrease the absorptivity of that region, thus decreasing the heat transferred to the particular location along the top surface 29. In a further example, in order to increase temperature uniformity across individual wafers, the wafer carrier 28 may be provided with modified emissivity regions associated with the individual wafer pockets 32 (e.g., regions 70a-c adjacent the wafer pockets 32 and/or regions 86 inside the wafer pockets 32). By providing combinations of the above-discussed coatings in various regions on the outer surface of the wafer carrier 28, the modified wafer carrier 28 will desirably exhibit increased uniformity of operating temperature.

Various different types of low-emissivity coatings (discussed above) may be provided on the wafer carrier 28. For example, the coating may comprise a paint having a relatively low emissivity (e.g., a white paint) that does not contaminate the CVD process and that can withstand the temperature conditions within the apparatus 10. One example of such a paint is a white, alumina (aluminum oxide) based compound made by Aremco Products, Inc. called Pyro-Paint™ 634-AL. In another example, the coating may comprise a white ceramic powder that is applied to the outer surface of the wafer carrier 28 and then baked to form a coating. The lower emissivity regions of the wafer carrier 28 need not be coatings, however. In another example, one or more of the regions of the wafer carrier 28 may include a thin strip of metal or foil having a lower emissivity than the outer surface of the wafer carrier 28. For example, a thin ring of molybdenum may be affixed along the outer edge 46 of the wafer carrier 28. Molybdenum has an emissivity in the range of 0.25 to 0.3.

The embodiment discussed above with reference to FIG. 1 is a “susceptorless” treatment apparatus, in which heat is transferred from the heater 38 directly to the bottom surface 31 of the wafer carrier 28. Similar principles to those discussed above can be applied in apparatus where the heat is transferred from the heating element to an intermediate element, commonly referred to as a “susceptor,” and transferred from the susceptor to the carrier. For example, portions of a susceptor may be provided with regions having a lower emissivity than other regions of the susceptor, in order to affect the temperature profile along the top surface of a wafer carrier disposed on the susceptor.

Although the above-discussed embodiments illustrate the technique of modifying the emissivity of portions of a wafer carrier by lowering the emissivity of certain regions on the outer surface of the wafer carrier, similar results may be obtained by increasing the emissivity of particular regions on the outer surface. For example, in order to lower the surface temperature of a particular location along the outer surface of a wafer carrier, a coating having a higher emissivity than the other surfaces of the carrier may be provided on the outer surface at that location. In another example, all other surfaces of the wafer carrier other than at the particular location may be provided with a lower emissivity coating, thus causing the emissivity of the particular location to be comparatively higher. Thus, the radiation from the outer surface of the wafer carrier at the particular location may be higher than from other portions of the outer surface, which may desirably lower the surface temperature of the wafer carrier at that location.

### Illustrative Example

In one illustrative example, computer modeling was performed on a wafer carrier 28 used in a model K465 MOCVD system sold commercially under the registered trademark TURBODISC by Veeco Instruments, Inc. of Plainview, N.Y., USA, assignee of the present application. The wafer carrier 28, a partial cross-section of which is illustrated in FIG. 4, was modeled under typical growth conditions for growing InGaN (indium gallium nitride) semiconductors, including a top surface 29 temperature of approximately 750° C. The carrier 28 was modeled as graphite with a silicon carbide coating and had a diameter of 465 mm and a thickness of 15.9 mm. The emissivity of the wafer carrier 28 was modeled as being 0.85, and the rings 58, 64, 66 and outer edge coating 50 illustrated in FIG. 4 were modeled as having an emissivity of 0.25, which is the estimated effective emissivity of the Pyro-Paint™ 634-AL (mentioned above).

After generating computer models of the top surface 29 temperature profile with a variety of radial positions and widths of the rings 58, 64, 66, the curve 68 illustrated in FIG. 5 was generated. In generating curve 68, the ring 58 was given an inner diameter of 8 mm and a width of 5 mm, the ring 64 was given an inner diameter of 38 mm and a width of 5 mm, and the ring 66 was given an inner diameter of 406 mm and a width of 7.5 mm.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A wafer carrier comprising a body having an outer surface, the outer surface comprising oppositely-facing top and bottom surfaces and an edge surface extending between the top and bottom surfaces, the top surface defining a plurality of pockets adapted to receive wafers, the outer surface of the body including a first region having a substantially different emissivity than other regions of the outer surface.

2. The wafer carrier of claim 1, wherein the emissivity of the first region is substantially lower than the other regions of the outer surface of the body.

3. The wafer carrier of claim 1, wherein the first region comprises a coating having an emissivity substantially lower than the other regions of the outer surface of the body.

4. The wafer carrier of claim 3, wherein the body comprises a non-metallic refractory material, and wherein the coating is chemically and physically stable at temperatures in excess of 750° C.

5. The wafer carrier of claim 1, wherein the first region includes a thin strip of metal having an emissivity substantially lower than the other regions of the outer surface of the body, the thin strip of metal being affixed to the outer surface in the first region.

6. The wafer carrier of claim 1, wherein an emissivity of the first region is about 0.6 lower than an emissivity of the other regions of the outer surface.

7. The wafer carrier of claim 1, wherein the first region is disposed on the edge surface.

8. The wafer carrier of claim 1, wherein the first region is associated with at least one of the plurality of pockets.

9. The wafer carrier of claim 8, wherein the first region is disposed on the top surface adjacent to the at least one pocket.

10. The wafer carrier of claim 8, wherein the first region is disposed in one of the pockets.

11. The wafer carrier of claim 10, wherein the pockets each comprise a circular recess having a substantially flat floor surface, the first region being disposed on the floor surface and centered on a central axis of the circular recess.

12. The wafer carrier of claim 1, wherein the first region defines an emissivity gradient across at least a portion of the first region.

13. The wafer carrier of claim 1, wherein the outer surface of the body includes a second region having a substantially different emissivity than other regions of the outer surface.

14. The wafer carrier of claim 13, wherein the second region is disposed on either the bottom surface or the top surface.

15. The wafer carrier of claim 14, wherein the second region is disposed on the bottom surface proximate the outer edge surface.

16. The wafer carrier of claim 14, wherein the body is in the form of a circular disc having a central axis, the second region having the shape of a ring centered on the central axis.

17. The wafer carrier of claim 16, wherein the outer surface of the body includes a third and a fourth region having a substantially different emissivity than other regions of the outer surface.

18. The wafer carrier of claim 17, wherein the third region is disposed on the bottom surface, and wherein the fourth region is disposed on the top surface proximate the central axis of the body, the third and fourth regions each having the shape of a ring centered on the central axis.

19. A chemical vapor deposition apparatus, comprising:
(a) a reaction chamber;
(b) a gas inlet structure communicating with the reaction chamber;
(c) a wafer carrier as recited in claim 1, wherein the wafer carrier is mounted within the reaction chamber such that the top surface is exposed to gas emanating from the gas inlet structure; and
(d) a heater arranged to transmit heat to the wafer carrier.

20. The apparatus of claim 19, wherein the heater includes a plurality of individually adjustable heating elements.

21. The apparatus of claim 19, wherein the body of the wafer carrier is in the form of a circular disc having a central axis, and wherein a radially outer one of the individually adjustable heating elements is arranged to heat a peripheral zone along the circumference of the disc, the radially outer heating element having an annular shape centered on the central axis.

22. The apparatus of claim 21, wherein the first region is disposed on the outer edge surface, the first region extending around the circumference of the disc.

23. The apparatus of claim 21, wherein the outer surface of the body includes a second region disposed on either the bottom surface or the top surface, the second region having the shape of a ring centered on the central axis.

24. A method of processing wafers, comprising:
(a) rotating a wafer carrier as recited in claim 1 about an axis, the wafer carrier having a plurality of wafers disposed in the pockets, the wafers having top surfaces facing in an upstream direction substantially parallel to the axis;
(b) heating the wafer carrier during the rotating step; and
(c) treating the wafers during the rotating step.
